(19) United States
(12) Patent Application Publication
(10) Pub. No.: US 2013/0200572 A1
(43) Pub. Date: Aug. 8, 2013

(54) VEHICLE PISTON RING HAVING A NANO MULTI-LAYER COATING

(71) Applicants: Sung Chul Cha, Seoul (KR); Chang Hyun Shin, Incheon (KR); Ji Hwan Yun, Ansan (KR)

(72) Inventors: Sung Chul Cha, Seoul (KR); Chang Hyun Shin, Incheon (KR); Ji Hwan Yun, Ansan (KR)

(73) Assignees: KIA MOTORS CORPORATION, Seoul (KR); HYUNDAI MOTOR COMPANY, Seoul (KR)

(21) Appl. No.: 13/527,966

(22) Filed: Jun. 20, 2012

(30) Foreign Application Priority Data
Feb. 7, 2012 (KR) 10-2012-0012286

(51) Int. Cl. F16J 9/26; C23C 16/06

(52) U.S. Cl. 277/442; 427/255.394

(57) ABSTRACT

The present disclosure provides a vehicle piston ring having a multi-layer coating. The vehicle piston ring includes a Cr or Ti buffer layer, a CrN or Ti(C)N intermediate layer, a first TiAlN/CrN nano multi-layer, and a second TiAlCN/CrCN nano multi-layer. The Cr or Ti buffer layer is coated over the base material of the piston ring. The CrN or Ti(C)N intermediate layer is coated over the Cr or Ti buffer layer. The first TiAlN/CrN nano multilayer is coated over the CrN or Ti(C)N intermediate layer. The second TiAlCN/CrCN nano multilayer is coated over the first TiAlN/CrN nano multilayer as an outermost surface layer.

### CROSS-REFERENCE TO RELATED APPLICATION

This application claims under 35 U.S.C. §119 (a) the benefit of Korean Patent Application No. 10-2012-0012286 filed Feb. 7, 2012, the entire contents of which are incorporated herein by reference.

### BACKGROUND

(a) Technical Field

The present invention relates to a vehicle piston ring having a nano multi-layer coating. More particularly, it relates to a vehicle piston ring having a nano multi-layer coating, in which a TiAlCrCN nano multi-layer coating is coated on the outer circumferential surface of the base material of a piston ring to increase the abrasion resistance of the piston ring and improve the fuel efficiency of a vehicle due to reduction of a frictional loss between an engine cylinder and the piston ring.

(b) Background Art

Recently, “eco-friendly” vehicles have become the megatrend of next-generation vehicle development by the automobile industry, and various eco-friendly vehicles are being developed with the goal of reducing CO₂ emissions to about 50 g/km by 2020, which is about a 35% to 50% reduction compared to current emission levels. Also, vehicle manufacturers are trying to develop technologies for improving vehicle fuel efficiency to meet the 54.5 mpg (23.2 km/l) goal mandated by U.S. Corporate Average Fuel Economy (CAFE) for implementation by 2025. Thus, in order to increase the fuel efficiency in driving systems such as engines, there is a need for engine parts having functional characteristics such as low friction, abrasion resistance and heat resistance.

For example, a piston ring is a split ring that fits into a groove on the outer diameter of a piston, and functions to maintain airtightness between the piston and the inner wall of an engine cylinder. The piston ring also functions to scrape lubricant from the inner wall of the engine cylinder so that the lubricant does not flow into the combustion chamber. In this case, since frictional loss and abrasion occur in the cylinder due to the reciprocating movement, various conventional art coatings and surface treatments with low friction and high endurance have been applied to the outer circumferential surface of the piston ring in order to attempt to improve the functional properties of the piston ring.

For example, Cr plating and nitriding (gas nitriding) have been applied to the outer circumferential surface of the piston ring; however, they mainly function to improve abrasion resistance. Recently, various coating materials such as Diamond Like Carbon (DLC) and CrN have been used for low friction and endurance improvement. For example, CrN has been coated on the outer circumferential surface of a piston ring by a Physical Vapor Deposition (PVD) method, and has been found to have low friction, abrasion resistance, and scuff resistance properties that are better than those of Cr plating and nitriding.

Since DLC has excellent low friction and high hardness characteristics, it is typically being applied to sliding parts of engines. Unfortunately, hydrogen in DLC may be effused in an atmosphere of moisture and friction at a high temperature of about 300° C., thereby softening the DLC coating and deteriorating its friction resistance and durability.

Accordingly, there is a need for a coating for engine parts that overcomes these deficiencies in the conventional art.

### SUMMARY OF THE DISCLOSURE

The present invention provides a vehicle piston ring with a nano multi-layer coating, which provides heat resistance against a temperature of about 600° C. or more and abrasion resistance, as well as low friction characteristics. The multi-layer coating includes a coating structure in which a TiAlCrCN nano multi-layer coating containing carbon with low friction characteristics is coated as the outermost surface layer, and TiAlN/CrN containing heat-resistance elements (e.g., TiAl and Cr) with excellent heat resistance, toughness, and abrasion resistance is coated as an intermediate layer.

In one exemplary embodiment, the present invention provides a vehicle piston ring having a nano multi-layer coating, including: a Cr or Ti buffer layer coated over the base material of the piston ring; a CrN or Ti(C)N intermediate layer coated over the Cr or Ti buffer layer; a first TiAlN/CrN nano multi-layer coated over the CrN or Ti(C)N intermediate layer; and a second TiAlCN/CrCN nano multi-layer coated over the first TiAlN/CrN nano multilayer as an outermost surface layer.

In an exemplary embodiment, the Cr or Ti buffer layer may be formed to have a thickness of about 0.01 μm to about 0.5 μm.

In another exemplary embodiment, the CrN or Ti(C)N intermediate layer may be formed to have a thickness of about 0.1 μm to about 5 μm.

In still another exemplary embodiment, the first TiAlN/CrN nano multilayer may include TiAlN and CrN that are alternately coated to form a multi-layer coating.

In yet another exemplary embodiment, the first TiAlN/CrN nano multi-layer may include TiAlN nano layers with a thickness of about 10 nm to about 50 nm and CrN nano layers with a thickness of about 10 nm to about 50 nm, which are alternately coated to form a thickness of about 0.1 μm to about 10 μm.

In still yet another exemplary embodiment, the second TiAlCN/CrCN nano multilayer may include TiAlCN and CrCN that are alternately coated to form a multi-layer.

In a further exemplary embodiment, the second TiAlCN/CrCN nano multilayer may include TiAlCN nano layers with a thickness of about 10 nm to about 50 nm and CrCN nano layers with a thickness of about 10 nm to about 50 nm, which are alternately coated to form a thickness of about 0.1 μm to about 10 μm.

Other aspects and exemplary embodiments of the invention are discussed infra.

### BRIEF DESCRIPTION OF THE DRAWINGS

The above and other features of the present invention will now be described in detail with reference to certain exemplary embodiments thereof illustrated in the accompanying drawings which are given hereinbelow by way of illustration only, and thus are not limitative of the present invention, and wherein:

FIG. 1 is a view illustrating a nano multi-layer coating of a vehicle piston ring according to an exemplary embodiment of the present invention;

FIG. 2 is a view illustrating a stacked structure of a nano multi-coating layer of a vehicle piston ring according to an exemplary embodiment of the present invention;

FIG. 3 is a view illustrating a Physical Vapor Deposition (PVD) apparatus for forming a nano multi-layer coating on a vehicle piston ring according to an exemplary embodiment of the present invention;

FIGS. 4 and 5 are electron microscopic views illustrating a texture of a nano multi-layer coating of a vehicle piston ring according to an exemplary embodiment of the present invention;

FIG. 6 is a view illustrating a conventional art method for treating and coating the surface of a piston ring; and

FIG. 7 is a view illustrating a mounting location of a piston ring among vehicle parts.

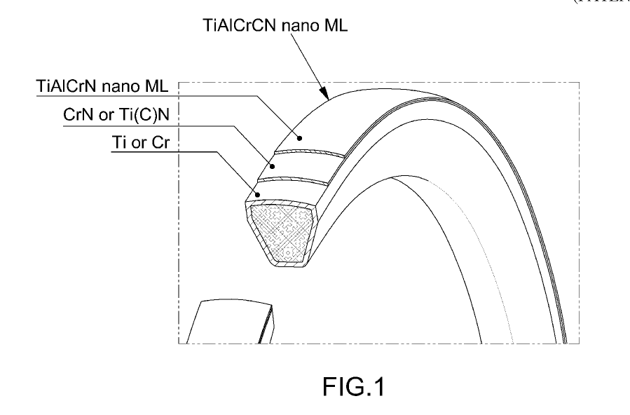

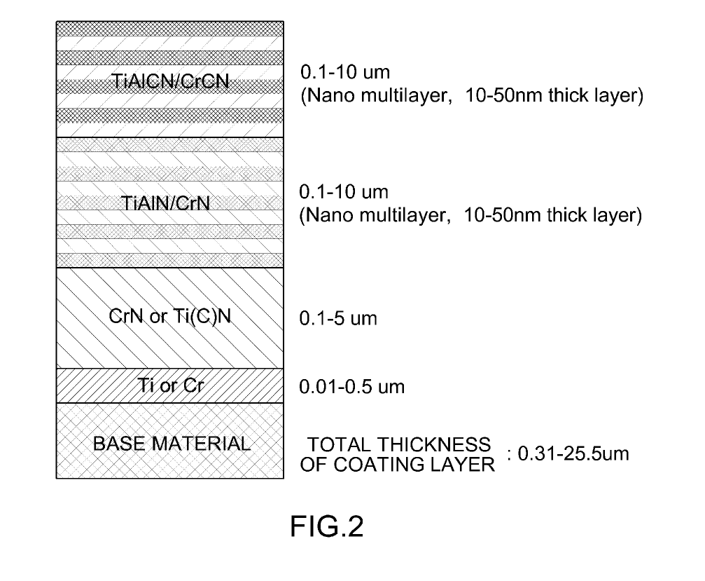

It should be understood that the appended drawings are not necessarily to scale, presenting a somewhat simplified representation of various preferred features illustrative of the basic principles of the invention. The specific design features of the present invention as disclosed herein, including, for example, specific dimensions, orientations, locations, and shapes will be determined in part by the particular intended application and use environment. In the figures, reference numbers refer to the same or equivalent parts of the present invention throughout the several figures of the drawing.

### DETAILED DESCRIPTION

Hereinafter reference will now be made in detail to various embodiments of the present invention, examples of which are illustrated in the accompanying drawings and described below. While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g., fuels derived from resources other than petroleum). As referred to herein, a hybrid vehicle is a vehicle that has two or more sources of power, for example both gasoline-powered and electric-powered vehicles.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Ranges provided herein are understood to be shorthand for all of the values within the range. For example, a range of 1 to 50 is understood to include any number, combination of numbers, or sub-range from the group consisting of 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, or 50, as well as all intervening decimal values between the aforementioned integers such as, for example, 1.1, 1.2, 1.3, 1.4, 1.5, 1.6, 1.7, 1.8, and 1.9. With respect to sub-ranges, “nested sub-ranges” that extend from either end point of the range are specifically contemplated. For example, a nested sub-range of an exemplary range of 1 to 50 may comprise 1 to 10, 1 to 20, 1 to 30, and 1 to 40 in one direction, or 50 to 40, 50 to 30, 50 to 20, and 50 to 10 in the other direction.

The above and other features of the invention are discussed infra.

Hereinafter, exemplary embodiments of the present invention will be described in detail with reference to the accompanying drawings.

The present invention provides a piston ring coating that enables about a 25% reduction in friction, about a 0.5% improvement in fuel efficiency, about a 56% improvement in scuff resistance, and about a 90% improvement in abrasion resistance compared to an uncoated piston ring (nitriding).

According to an exemplary embodiment of the invention, the piston ring coating includes a Ti or Cr buffer layer, a CrN or Ti(C)N intermediate layer, a first TiAlN/CrN nano multilayer, and a second TiAlCN/CrCN nano multi-layer that may be sequentially coated over an outer circumferential surface of a base material of the piston ring by a Physical Vapor Deposition (PVD) method.

According to an exemplary embodiment, the Cr or Ti buffer layer may be coated on the surface of the base material of the piston ring to a thickness of about 0.01 μm to about 0.5 μm. The CrN or Ti(C)N intermediate layer may be coated on the Cr or Ti buffer layer to a thickness of about 0.1 μm to about 5 μm. The first TiAlN/CrN nano multilayer may be coated on the CrN or Ti(C)N intermediate layer to a thickness of about 0.1 μm to about 10 μm. The second TiAlCN/CrCN nano multi-layer that is the outermost surface layer may be coated on the first TiAlN/CrN nano multi-layer to a thickness of about 0.1 μm to about 10 μm.

Hereinafter, the functions of each layer coated over the piston ring will be described as follows.

### Cr or Ti Buffer Layer

The Cr or Ti buffer layer may have an excellent bonding strength with the base material of the piston ring, and may serve to reduce and control the residual stress of other coating layers. In order to achieve such a function, the Cr or Ti buffer layer may be coated on the surface of the base material of the piston ring to a thickness of about 0.01 μm to about 0.5 μm.

### CrN or Ti(C)N Intermediate Layer

The CrN or Ti(C)N intermediate layer may be coated on the Cr or Ti buffer layer to a thickness of about 0.1 μm to about 5 μm to provide toughness, fatigue resistance, and shock resistance.

### First TiAlN/CrN Nano Multi-Layer

The first TiAlN/CrN nano multilayer may contain heat-resistance elements (e.g., TiAl and Cr) with excellent heat resistance and abrasion resistance, and may include TiAlN and CrN nano layers that are alternately coated on the surface of the CrN or Ti(C)N intermediate layer to provide excellent toughness. The TiAlN and CrN nano layers with a thickness of about 10 nm to about 50 nm may be alternately coated to form a total thickness of about 0.1 μm to about 10 μm.

### Second TiAlCN/CrCN Nano Multi-Layer

The second TiAlCN/CrCN nano multilayer may further include carbon (C) of about 5 atomic percent (at %) to about 30 at %

with excellent low friction characteristics in addition to the components constituting the first nano multilayer, and may form the outermost surface layer of the multi-layer coating. The second TiAlCN/CrCN nano multi-layer may include TiAlCN nano layers and CrCN nano layers that have a thickness of about 10 nm to about 50 nm and are alternately coated on each other to form a total thickness of about 0.1 μm to about 10 μm.

Hereinafter, a method of coating a vehicle piston ring according to an embodiment of the present invention will be described.

The piston ring having a nanostructure multi-layer coating may be formed by a Physical Vapor Deposition (PVD) method. In addition, High Power Impulse Magnetron Sputtering (HIPIMS), Inductively Coupled Plasma (ICP) Magnetron Sputtering, and arch methods for generating high density plasma to implement nanosizing of coating material particles and high speed coating may be used.

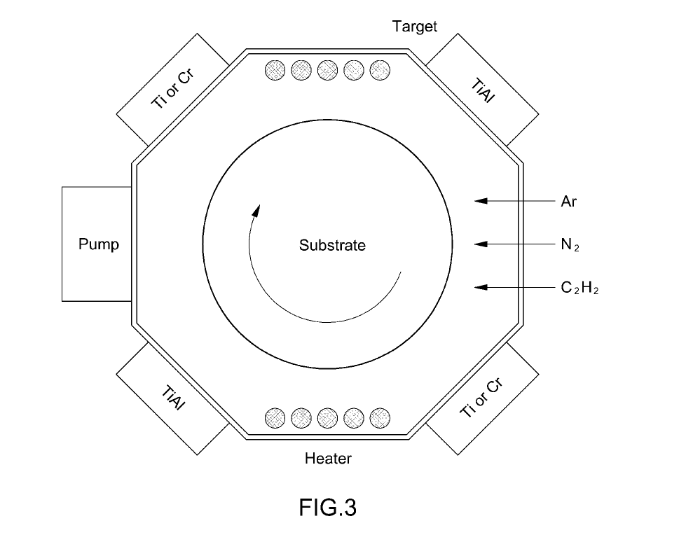

FIG. 3 illustrates a PVD coating apparatus for coating a nano multi-layer coating on a piston ring according to an exemplary embodiment of the present invention. The PVD coating apparatus may include a pair of Ti or Cr targets opposite to each other, a pair of TiAl targets opposite to each other, and a gas supply unit for supplying Ar, N2 and hydrocarbon process gases.

For a coating process using the PVD coating apparatus, a plasma state may be prepared using Ar gas in a vacuum state prior to coating. Thereafter, a coating chamber may be heated to a temperature of about 80° C. to activate the surface of the piston ring, and then the surface of the piston ring may be cleaned by applying a bias while allowing Ar ions to collide with the surface of the piston ring (baking & cleaning).

Next, in order to provide excellent bonding strength with the base material of the piston ring and reduce the residual stress of coating, a Ti or Cr layer may be coated on the base material surface of the piston ring to a thickness of about 0.01 μm to about 0.5 μm using only the Ti or Cr targets.

An intermediate layer providing toughness, fatigue resistance and shock resistance, a CrN layer formed by flowing the process gas N2 to react with Cr ions from the Cr target, or a TiN or TiCN layer formed by flowing C₂H₂ and N₂ to react with Ti ions from the Ti target, may then be coated on the surface of the Ti or Cr layer to a thickness of about 0.1 μm to about 5 μm.

A TiAlN/CrN nano multilayer containing heat-resistance elements (e.g., TiAl and Cr) with excellent heat resistance and abrasion resistance and having excellent toughness may then be coated on the TiN or TiCN layer. In this case, the TiAlN nano layer and the CrN nano layer having a thickness of about 10 nm to about 50 nm may be alternately coated using the TiAl target, the Cr target, and the process gas N2 to form a total thickness of about 0.1 μm to about 10 μm.

TiAlCrCN containing about 5 wt % to about 30 wt % carbon (C) with excellent friction characteristics may then be coated on the outermost surface. For this, the TiAlCN nano layer and the CrCN nano layer having a thickness of about 10 nm to about 50 nm, respectively, may be alternately coated using the TiAl target, the Cr target and the process gases C₂H₂ and N₂ to form a total thickness of about 0.1 μm to about 10 μm.

Hereinafter, an exemplary embodiment of the present invention will be described in more detail.

### Example

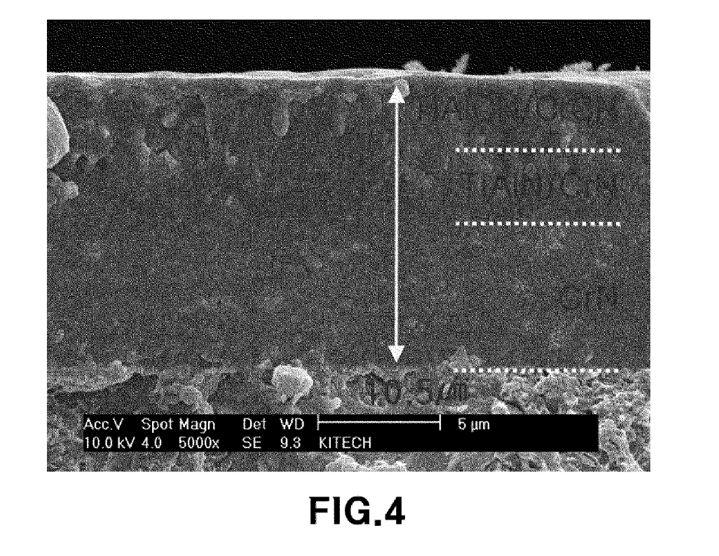

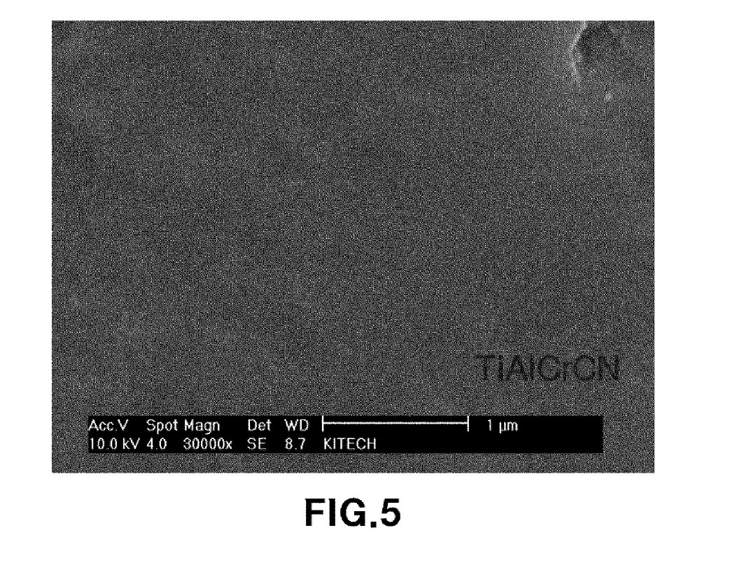

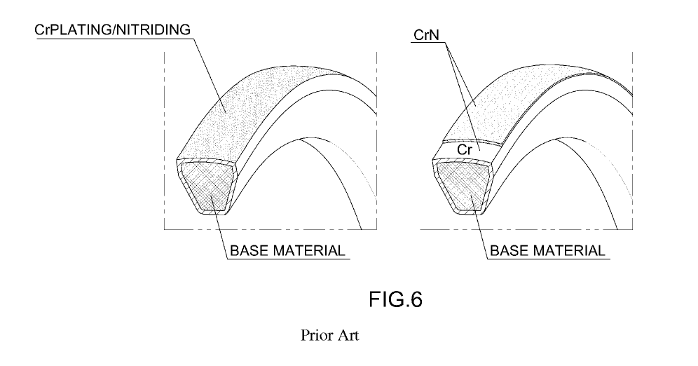

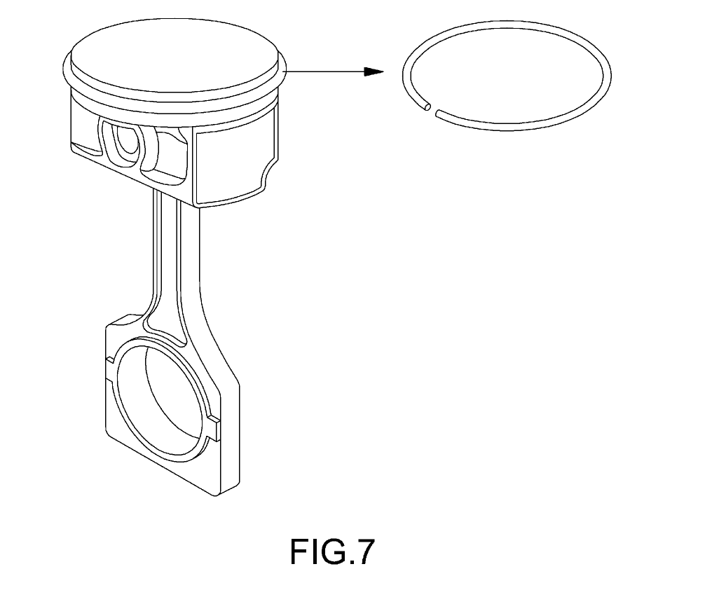

As shown in Table 1 below, a Cr buffer layer having a thickness of about 0.5 μm was coated on the surface of the base material of a piston using a PVD method, and then a CrN intermediate layer having a thickness of about 5 μm was coated on the Cr buffer layer. Thereafter, a first TiAlCrN nano multi-layer having a thickness of about 2.5 μm was coated on the CrN intermediate layer, followed by a second TiAlCrCN nano multi-layer coated thereon as the outermost surface layer. The coating texture is shown in FIGS. 4 and 5.

TABLE 1

| | Comparative | Comparative | Comparative | |
|---|---|---|---|---|
| | Example 1 | Example 2 | Example 3 | Example |
| Surface | Nitriding | CrN | DLC | TiAlCrCN |
| treatment/coating | | | | |
| Method | — | PVD | PVD | PVD |
| Thickness | 20 | 5 | 2.1 | 10.5 |
| | | | (0.1Cr—0.5WC-1.5DLC) | (0.5Cr—5CrN—2.5TiAlCrN—2.5TiAlCrCN) |

### Comparative Examples 1 to 3

As shown in Table 1, in a comparative example 1, a nitride layer having a thickness of about 20 μm was formed on the base material of a piston ring using a nitriding method for the comparative example 1. In comparative example 2, CrN having a thickness of about 5 μm was coated on the base material surface of the piston ring by the PVD method. In comparative example 3, a DLC coating layer (0.1Cr-0.5WC-1.5DLC) was coated to a thickness of about 2.15 μm by the PVD method.

### Test Examples 1 to 4

As test example 1, the friction coefficient between a cylinder liner and coated piston rings of the example and the comparative examples 1 to 3 was measured using a reciprocating friction/abrasion tester. The test was performed for about one hour under oil condition at a load of about 150 N, temperature of about 150° C., and reciprocating period of about 5 Hz.

As test example 2, a scuffing generation load between a cylinder liner and coated piston rings of the example and the comparative examples 1 to 3 was measured using a reciprocating friction/abrasion tester, and resistances against oil film destruction were compared to assess scuff resistances. The test was performed under oil condition of increasing load by 20 N every 20 minutes to about 500 N, temperature of about 150° C., and reciprocating period of about 5 Hz.

As test example 3, for a comparison of high-temperature abrasion resistances between a cylinder liner and coated piston rings of the example and the comparative examples 1 to 3, the amount of abrasion was measured using the reciprocating friction/abrasion tester. The test was performed for about one hour under oil condition at a load of about 150 N, temperature of about 200° C. and reciprocating period of about 5 Hz.

As test example 4, the bonding strength and the hardness of the respective coating layers of the piston ring according to the example and the comparative examples 1 to 3 were measured using typical equipment.

The measurement results of the test examples 1 to 4 are shown in Table 2 below.

TABLE 2

| | Comparative | Comparative | Comparative | |
|---|---|---|---|---|
| | Example 1 | Example 2 | Example 3 | Example |
| Surface | Nitriding | CrN | DLC | TiAlCrCN |
| treatment/coating | | | | |
| Friction | 0.11 | 0.095 | 0.09 | 0.0825 |
| coefficient (—) | | | | |
| Scuffing load (N) | 220 | 340 | 440 | 500 |
| High-temperature | 2.0 | 0.7 | 1.6 | 0.2 |
| abrasion | | | | |
| resistance | | | | |
| (μm/100 h) | | | | |
| Bonding strength | — | 44 | 40 | 50 |
| (N) | | | | |
| Hardness (HV) | 1,000 | 2,524 | 3,142 | 3,458 |

As shown in Table 2, the friction coefficient and the high-temperature abrasion resistance of the piston ring according to the exemplary embodiment of the present invention are better than those of the comparative examples 1 to 3. Also, since the scuffing load was measured to be about 500 N when the oil film is broken, the scuffing load of the example was better than those of the comparative examples 1 to 3, and the bonding strength and the hardness of the example were better than the comparative examples 1 to 3.

According to embodiments of the present invention, the present invention provides the following effects.

Heat resistance against a temperature of about 600° C. or more, abrasion resistance, and low friction characteristics can be simultaneously secured by providing a piston ring in which a Cr or Ti buffer layer and a CrN or Ti(C)N intermediate layer on a base material of the piston ring are sequentially coated, a TiAlN/CrN nano layer containing heat-resistance elements (e.g., TiAl and Cr) with excellent heat resistance and abrasion resistance and having excellent toughness is coated on the CrN or Ti(C)N intermediate layer as an intermediate layer, and then a TiAlCN/CrCN nano multi-layer containing carbon with excellent low friction characteristics is coated as the outermost surface layer. Since the friction coefficient of TiAlCrCN is lower by about 25% and about 13% than can be achieved by either nitriding or CrN, respectively, reduction of frictional loss of a piston ring and fuel efficiency improvement (e.g., about 0.2% to about 0.5%) can be achieved. Also, since the scuff resistance of TiAlCrCN is better by about 56% and about 32% than nitriding and CrN, respectively, the oil film destruction can also be inhibited, and the durability can be improved. Particularly, since the abrasion resistance of TiAlCrCN is better by about 90% and about 70% than nitriding and CrN, respectively, and a TiAlCrN multi-layered structure exists thereunder as an intermediate layer, the durability of a piston ring can be achieved.

In addition, as elements with excellent heat resistance against a high temperature of about 600° C. are coated, limitations in the heat resistance of typical DLC and deficiency in low friction characteristics of CrN can be overcome.

The invention has been described in detail with reference to exemplary embodiments thereof. However, it will be appreciated by those skilled in the art that changes may be made in these embodiments without departing from the principles and spirit of the invention, the scope of which is defined in the appended claims and their equivalents.

What is claimed is:

1. A piston ring having a multi-layer coating, comprising:
a buffer layer comprising Cr or Ti; an intermediate layer comprising CrN or Ti(C)N; a first TiAlN/CrN layer; and a second TiAlCN/CrCN layer,
wherein the buffer layer contacts the piston ring, the intermediate layer contacts the buffer layer, the first TiAlN/CrN layer contacts the intermediate layer, and the second TiAlCN/CrCN layer contacts the first TiAlN/CrN layer and is an outermost layer.

2. The piston ring having a multi-layer coating of claim 1, wherein the buffer layer has a thickness that ranges from about 0.01 μm to about 0.5 μm.

3. The piston ring having a multi-layer coating of claim 1, wherein the intermediate layer has a thickness that ranges from about 0.1 μm to about 5 μm.

4. The piston ring having a multi-layer coating of claim 1, wherein the first TiAlN/CrN layer comprises at least one TiAlN layer and at least one CrN layer.

5. The piston ring having a multi-layer coating of claim 4, wherein the at least one TiAlN layer and the at least one CrN layer are alternating layers.

6. The piston ring having a multi-layer coating of claim 4, wherein the at least one TiAlN layer has a thickness that ranges from about 10 nm to about 50 nm, and the at least one CrN layer has a thickness that ranges from about 10 nm to about 50 nm.

7. The piston ring having a multi-layer coating of claim 4, wherein the at least one TiAlN layer and the at least one CrN layer are alternating layers that form the first TiAlN/CrN layer with a thickness that ranges from about 0.1 μm to about 10 μm.

8. The piston ring having a multi-layer coating of claim 1, wherein the second TiAlCN/CrCN layer comprises at least one TiAlCN layer and at least one CrCN that are alternately coated to form the second TiAlCN/CrCN layer.

9. The piston ring having a multi-layer coating of claim 8, wherein the at least one TiAlN layer has a thickness that ranges from about 10 nm to about 50 nm, and the at least one CrN layer has a thickness that ranges from about 10 nm to about 50 nm.

10. The piston ring multi-layer coating of claim 9, wherein the at least one TiAlN layer and the at least one CrN layer are alternating layers that form the second TiAlN/CrN layer with a thickness that ranges from about 0.1 μm to about 10 μm.

11. A method of preparing the piston ring having a multi-layer coating of claim 1, comprising:
(a) cleaning the piston ring by applying a bias while allowing Ar ions to collide with the piston ring;
(b) applying Ti or Cr to the piston ring to form the buffer layer;
(c) forming the CrN intermediate layer by flowing N2 to react with Cr ions from a Cr target, or forming the Ti(C)N intermediate layer by flowing C₂H₂ and N₂ to react with Ti ions from a Ti target;
(d) forming a first TiAlN/CrN layer by alternately flowing N2 to react with a TiAl target to form a TiAlN sub-layer and flowing N2 to react with a Cr target to form a CrN sub-layer; and
(e) forming a second TiAlN/CrN layer by alternately flowing N2 to react with a TiAl target to form a TiAlN sub-layer and flowing N2 to react with a Cr target to form a CrN sub-layer.

12. The method of claim 11, wherein cleaning occurs at about 80° C.

13. The method of claim 11, wherein the Cr or Ti is applied to a thickness that ranges from about 0.01 μm to about 0.5 μm.

14. The method of claim 11, wherein the intermediate layer is formed to a thickness that ranges from about 0.1 μm to about 5 μm.

15. The method of claim 11, wherein the TiAlN sub-layers range in thickness from about 10 nm to about 50 nm.

16. The method of claim 11, wherein the CrN sub-layers range in thickness from about 10 nm to about 50 nm.

17. The method of claim 11, wherein the first TiAlN/CrN layer has a total thickness ranging from about 0.1 μm to about 10 μm.

18. The method of claim 11, wherein the second TiAlN/CrN layer has a total thickness ranging from about 0.1 μm to about 10 μm.
